(19) United States
(12) Patent Application Publication
(10) Pub. No.: US 2007/0297220 A1
(43) Pub. Date: Dec. 27, 2007

(54) MAGNETORESISTIVE ELEMENT AND MAGNETIC MEMORY

(76) Inventors: Masatoshi YOSHIKAWA, Yokohama-shi (JP); Tadashi Kai, Tokyo (JP); Toshihiko Nagase, Sagamihara-shi (JP); Tatsuya Kishi, Yokohama-shi (JP); Hiroaki Yoda, Sagamihara-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 11/626,042

(22) Filed: Jan. 23, 2007

(30) Foreign Application Priority Data
Jun. 22, 2006 (JP) 2006-172844

(51) Int. Cl. G11C 11/00

(52) U.S. Cl. 365/158

(57) ABSTRACT

A magnetoresistive includes a first magnetic reference layer having a fixed magnetization direction, a magnetic free layer having a magnetization direction which is changeable by being supplied with spin polarized electrons, a second magnetic reference layer having a fixed magnetization direction, a first intermediate layer provided between the first magnetic reference layer and the magnetic free layer, and a second intermediate layer provided between the magnetic free layer and the second magnetic reference layer. The magnetic free layer and the first magnetic reference layer have directions of easy magnetization perpendicular or parallel to an in-plane direction. The first magnetic reference layer and the second magnetic reference layer have directions of easy magnetization perpendicular to each other.

### CROSS-REFERENCE TO RELATED APPLICATIONS

This application is based upon and claims the benefit of priority from prior Japanese Patent Application No. 2006-172844, filed Jun. 22, 2006, the entire contents of which are incorporated herein by reference.

### BACKGROUND OF THE INVENTION

1. Field of the Invention

The present invention relates to a magnetoresistive element and a magnetic memory and, for example, to a magnetoresistive element capable of recording data by supplying a current bidirectionally and a magnetic memory using the magnetoresistive element.

2. Description of the Related Art

There are recently proposed a number of solid-state memories that record data on the basis of a new principle. Among them all, a magnetoresistive random access memory (MRAM) using a tunneling magnetoresistive (TMR) effect is especially receiving a great deal of attention as a solid-state magnetic memory. As a characteristic feature, an MRAM stores data in accordance with the magnetization state of a magnetic tunnel junction (MTJ) element.

In a conventional MRAM that writes data in accordance with a magnetic field by an interconnection current, when the MTJ element size decreases, a coercive force Hc increases, and therefore, the current necessary for writing tends to increase. In fact, to manufacture an MRAM with a large capacity of 256 Mbits or more, the chip size must be small. For this purpose, it is necessary to decrease the write current to the μA level while suppressing size reduction of the MTJ element by increasing the cell array occupation ratio in the chip. However, reduction of the MTJ element size and reduction of the write current are mutually exclusive. For this reason, the conventional MRAM can hardly reduce both the cell size and the current to attain a capacity greater than 256 Mbits.

There is proposed an MRAM using spin momentum transfer (SMT) to solve the above-described problem (e.g., U.S. Pat. No. 6,256,223; reference 1 [C. Slonczewski, “Current-driven Excitation of Magnetic Multilayers”, Journal of Magnetism and Magnetic Materials, Vol. 159, 1996, pp. L1-L7]; and reference 2 [L. Berger, “Emission of Spin Waves by a Magnetic Multilayer Traversed by a Current”, Physical Review B, Vol. 54, No. 13, 1996, pp. 9353-8]). In spin momentum transfer (to be referred to as “spin injection” hereinafter) switching, a current density Jc defines a magnetization switching current Ic necessary for switch. Hence, when the element area decreases, the switching current Ic to cause switch by spin injection also decreases.

If the current density is constant in the write mode, the write current also decreases as the MTJ element size decreases. Hence, the MRAM of this type is expected to have excellent scalability as compared to the conventional field-write-type MRAM. In the current spin injection MRAM, however, the current density Jc necessary for switch is very high, i.e., 10 mA/cm² or more. Use of even an MTJ element having a size of 100 nm² requires a write current of about 1 mA.

This is because the spin injection switching scheme requires bidirectional energization, and the spin injection efficiency changes depending on the energization direction. That is, the spin injection switching curve is asymmetric. The current to switch the magnetization direction of a magnetic free layer (free layer) to change the magnetization arrangements of the free layer and magnetic reference layer (pinned layer) from parallel to antiparallel needs to be about twice that in changing from antiparallel to parallel.

A problem of this asymmetric curve will be described. If a tunneling magnetoresistive (TMR) effect film is used, and writing is done by energizing to switch the magnetization arrangements of the free layer and pinned layer from antiparallel to parallel, no problem is posed because the threshold current is small. However, if writing is done at a predetermined current density Ia-ap by energizing to switch the magnetization arrangements of the free layer and pinned layer from parallel to antiparallel, an element resistance Rap in the antiparallel magnetization arrangement rises in accordance with the TMR effect because of the large write current. As a result, the write voltage Vp-ap rises.

Hence, if the breakdown voltage of the tunnel barrier layer is not sufficiently high, the layer reaches a breakdown voltage Vbd and causes dielectric breakdown before obtaining the antiparallel magnetization arrangement. Additionally, no operational reliability at a high voltage is ensured even without dielectric breakdown.

### BRIEF SUMMARY OF THE INVENTION

According to a first aspect of the present invention, there is provided a magnetoresistive element comprising: a first magnetic reference layer having a magnetization direction; a magnetic free layer having a magnetization direction which is changeable by being supplied with spin polarized electrons; a second magnetic reference layer having a magnetization direction; a first intermediate layer provided between the first magnetic reference layer and the magnetic free layer; and a second intermediate layer provided between the magnetic free layer and the second magnetic reference layer. The magnetic free layer and the first magnetic reference layer have directions of easy magnetization perpendicular or parallel to an in-plane direction. The first magnetic reference layer and the second magnetic reference layer have directions of easy magnetization perpendicular to each other.

According to a second aspect of the present invention, there is provided a magnetic memory comprising a memory cell including: the magnetoresistive element; and a first electrode and a second electrode which supply the current to the magnetoresistive element.

### BRIEF DESCRIPTION OF THE SEVERAL VIEWS OF THE DRAWING

FIG. 1 is a sectional view illustrating an MTJ element 10 according to the first embodiment;

FIG. 2 is a sectional view illustrating a detailed example of the MTJ element 10 according to the first embodiment;

FIG. 3 is a sectional view illustrating another structure of a pinned layer 15 according to the first embodiment;

FIG. 4 is a sectional view illustrating another structure of a pinned layer 11 according to the first embodiment;

FIG. 5 is a sectional view illustrating still another structure of the pinned layer 11 according to the first embodiment;

FIG. 6 is a sectional view illustrating another structure of a free layer 13 and pinned layer 11 according to the first embodiment;

FIG. 7 is a sectional view illustrating an MTJ element 10 according to the second embodiment;

FIG. 8 is a sectional view illustrating a detailed example of the MTJ element 10 according to the second embodiment;

FIG. 9 is a sectional view illustrating another structure of a free layer 13 according to the second embodiment;

FIG. 10 is a perspective view illustrating an MTJ element 10 according to the third embodiment;

FIG. 11 is a perspective view illustrating a detailed example of the MTJ element 10 according to the third embodiment;

FIG. 12 is a perspective view illustrating another structure of a pinned layer 15 according to the third embodiment;

FIG. 13 is a perspective view illustrating still another structure of the pinned layer 15 according to the third embodiment;

FIG. 14 is a circuit diagram illustrating an MRAM according to the fourth embodiment;

FIG. 15 is a sectional view illustrating an MRAM so as to mainly show an MTJ element 10; and

FIG. 16 is a sectional view illustrating another structure of the MRAM so as to mainly show the MTJ element 10.

### DETAILED DESCRIPTION OF THE INVENTION

The embodiments of the present invention will be described below with reference to the accompanying drawing. The same reference numerals denote elements having the same functions and arrangements in the description, and a repetitive description will be done only if necessary.

### First Embodiment

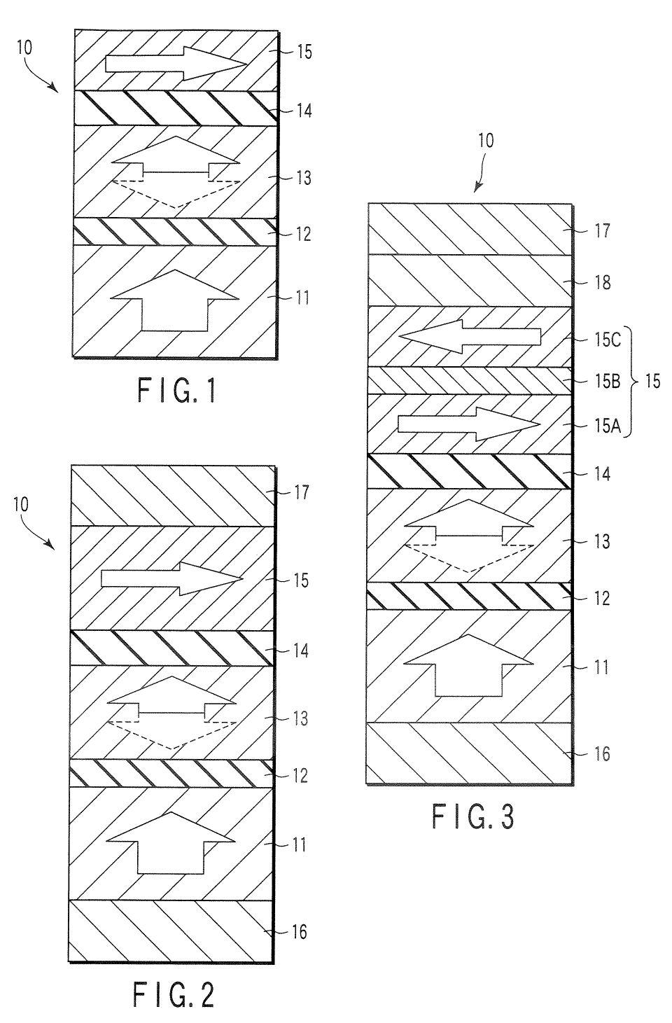

FIG. 1 shows the basic structure of the MTJ element 10 according to the first embodiment. Arrows in FIG. 1 indicate magnetization directions.

The MTJ element 10 has a layered structure of a first magnetic reference layer (pinned layer) 11, first intermediate layer 12, magnetic free layer (free layer) 13, second intermediate layer 14, and second magnetic reference layer (pinned layer) 15 which are stacked in this order. In this basic structure, the order of stacked layers may reverse.

The pinned layers 11 and 15 have fixed magnetization (or spin) directions. The magnetization direction of the free layer 13 changes (switches). The direction of easy magnetizations of the pinned layer 11 and free layer 13 are perpendicular to the film surface (or the in-plane direction) (this state will be referred to as “perpendicular magnetization” hereinafter). The direction of easy magnetization of the pinned layer 15 is parallel to the film surface (this state will be referred to as “in-plane magnetization” hereinafter). That is, the directions of easy magnetization of the pinned layers 11 and 15 are perpendicular to each other.

The direction of easy magnetization is a direction that minimizes the internal energy of a certain ferromagnetic material with a macro size when its spontaneous magnetization turns to the direction without any external magnetic field. The direction of hard magnetization is a direction that maximizes the internal energy of a certain ferromagnetic material with a macro size when its spontaneous magnetization turns to the direction without any external magnetic field.

In this embodiment, a perpendicular magnetization film is used as the free layer 13. Use of a perpendicular magnetization film for the free layer 13 makes it possible to design an aspect ratio Ar of the MTJ element size (the ratio of the short side length to the long side length of an element, i.e., Ar=long side length/short side length) to 1. In an in-plane magnetization film, a shape magnetic anisotropy energy decides an anisotropic magnetic field (Hk) necessary for thermal stability so that the aspect ratio of the MTJ element is lower than 1. To the contrary, in a perpendicular magnetization film, a magnetocrystalline anisotropy energy ensures the anisotropic magnetic field (Hk) necessary for thermal stability. That is, the anisotropic magnetic field (Hk) does not depend on the aspect ratio of the MTJ element.

This allows to reduce the MTJ element size. In an in-plane magnetization film and a perpendicular magnetization film which have the same MTJ element width and use TMR films that require the same current density Jc necessary for switch by spin injection, a spin injection switching current Ic is smaller in the perpendicular magnetization film because of the lower aspect ratio Ar.

In the MTJ element 10 having the above-described arrangement, data is written in the following way. In this embodiment, a current indicates a flow of electrons. First, a current flows in the MTJ element 10 bidirectionally in directions perpendicular to the film surface (or stacking plane).

This supplies electron spin polarized to majority and minority to the free layer 13. The spin angular momentum of majority electron spin moves to the free layer 13. A spin torque is applied to the free layer 13 to cause magnetization rotation of the free layer 13. The spin torque is represented by the outer product of the unit vectors of the magnetization directions of the pinned layer and free layer. Hence, the spin torque can be applied from both the two pinned layers perpendicular to each other to the free layer 13. Hence, the switching current by spin injection can decrease.

More specifically, when electrons are supplied from the side of the pinned layer 11 (i.e., electrons move from the pinned layer 11 to the free layer 13), electrons that are spin-polarized in the same direction as the direction of easy magnetization of the pinned layer 11 and electrons that are reflected by the pinned layer 15 and therefore spin-polarized in a direction reverse to the direction of easy magnetization of the pinned layer 15 are injected in the free layer 13. In this case, the magnetization direction of the free layer 13 is the same as the direction of easy magnetization of the pinned layer 11. That is, the magnetization directions of the pinned layer 11 and free layer 13 are parallel. The resistance of the MTJ element 10 is minimum in this parallel arrangement. This state is defined as binary 0.

On the other hand, when electrons are supplied from the side of the pinned layer 15 (i.e., electrons move from the pinned layer 15 to the free layer 13), electrons that are spin-polarized in the same direction as the direction of easy magnetization of the pinned layer 15 and electrons that are reflected by the pinned layer 11 and therefore spin-polarized in a direction reverse to the direction of easy magnetization of the pinned layer 11 are injected in the free layer 13. In this case, the magnetization direction of the free layer 13 is reverse to the direction of easy magnetization of the pinned layer 11. That is, the magnetization directions of the pinned layer 11 and free layer 13 are antiparallel. The resistance of the MTJ element 10 is maximum in this antiparallel arrangement. This state is defined as binary 1.

Data is read in the following way. A read current is supplied to the MTJ element 10 to detect a change in the resistance of the MTJ element 10. The read current is set to be smaller than the write current.

The direction of easy magnetization of the free layer 13 is perpendicular to the film surface. Hence, a magnetoresistive effect appears, via the intermediate layer 12, between the free layer 13 and the pinned layer 11 with a parallel magnetization arrangement. However, no magnetoresistive effect appears, via the intermediate layer 14, between the free layer 13 and the pinned layer 15 with a perpendicular magnetization arrangement. This is a large advantage that allows to avoid degradation in the read output by the second pinned layer, which poses a problem in a magnetoresistive element having a dual-pin layered structure (i.e., two pinned layers are arranged on both sides of a free layer via intermediate layers).

That is, in the MTJ element 10 of this embodiment, the magnetization directions of the two pinned layers (pinned layers 11 and 15) are perpendicular to each other. For this reason, if both the intermediate layers 12 and 14 use the same material, i.e., the same insulating material such as magnesium oxide (MgO) or aluminum oxide (AlOₓ), a high spin injection efficiency is available by the two pinned layers. In addition, the magnetoresistive effect appears in only one pinned layer.

In a conventional dual-pin layered structure, reciprocal magnetoresistive effects appear in both the intermediate layers 12 and 14. For this reason, the TMR ratio necessary for the read decreases. This embodiment can however avoid this problem.

A more detailed example of the MTJ element 10 according to this embodiment will be described next. FIG. 2 is a sectional view illustrating a detailed example of the MTJ element 10. In, e.g., the planar shape, the aspect ratio of the free layer 13 is set to almost 1.

An underlying layer 16 to control the crystal orientation or crystallinity of the basic structure exists at the lowermost portion on the side of a substrate (not shown). The underlying layer 16 uses, e.g., a nonmagnetic metal layer. A cap layer 17 to protect the basic structure from degradation such as oxidation or corrosion exists at the uppermost portion. The cap layer 17 uses, e.g., a nonmagnetic metal layer.

FIG. 3 is a sectional view illustrating another structure of the pinned layer 15. The direction of easy magnetization of the pinned layer 15 is parallel to the film surface. The pinned layer 15 has a layered structure of a pinned layer 15C, intermediate layer 15B, and pinned layer 15A. An antiferromagnetic layer 18 exists on the pinned layer 15C (between the pinned layer 15 and the cap layer 17) and contacts the pinned layer 15C. The pinned layer 15C exchange-couples with the antiferromagnetic layer 18 so that the magnetization direction is fixed in parallel to the film surface.

The directions of easy magnetization of the pinned layers 15A and 15C are parallel to the film surface. The magnetization directions of the pinned layers 15A and 15C are antiparallel (reverse) to each other. The pinned layers 15A and 15C antiferromagnetically couple with each other through the intermediate layer 15B. A layered structure of a first magnetic layer, intermediate layer (nonmagnetic layer), and second magnetic layer in which the magnetization directions of the magnetic layers via the intermediate layer are antiparallel is called a synthetic anti-ferromagnetic (SAF) structure. Use of the SAF structure strengthens the magnetization fixing force of the pinned layer 15 so that the resistance and thermal stability against an external magnetic field improve. More specifically, the temperature dependence of the magnetization fixing force of the pinned layer 15 improves.

In the SAF structure, let Ms1 be the saturation magnetization of the first magnetic layer (equivalent to the pinned layer 15C), t1 be the thickness of the first magnetic layer, Ms2 be the saturation magnetization of the second magnetic layer (equivalent to the pinned layer 15A), and t2 be the thickness of the second magnetic layer. When Ms1·t1≅Ms2·t2, apparently the product Ms·t of the saturation magnetization and the magnetic layer thickness of the pinned layer 15 can be almost zero. Since the pinned layer 15 hardly reacts to the external magnetic field, the resistance against the external magnetic field can further improve.

The intermediate layer 15B in the SAF structure uses a metal material such as ruthenium (Ru) or osmium (Os). The thickness of the intermediate layer 15B is set to 3 nm or less. This structure allows to obtain sufficiently strong antiferromagnetic coupling through the intermediate layer 15B. Use of the intermediate layer 15B with such a structure strengthens the magnetization fixing force of the pinned layer 15 so that the resistance and thermal stability against an external magnetic field improve.

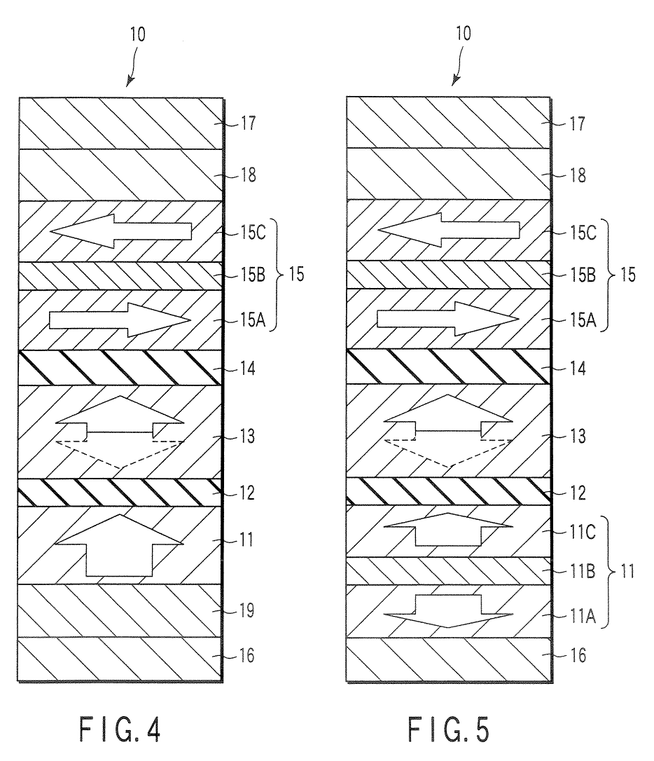

FIG. 4 is a sectional view illustrating another structure of the pinned layer 11. An antiferromagnetic layer 19 exists under the pinned layer 11 (between the pinned layer 11 and the underlying layer 16) and contacts the pinned layer 11. The pinned layer 11 exchange-couples with the antiferromagnetic layer 19 so that the magnetization direction is fixed perpendicularly to the film surface. Use of this structure strengthens the magnetization fixing force of the pinned layer 11 so that the resistance and thermal stability against an external magnetic field improve.

FIG. 5 is a sectional view illustrating still another structure of the pinned layer 11. The pinned layer 11 has a layered structure of a pinned layer 11C, intermediate layer 11B, and pinned layer 11A. That is, the pinned layer 11 has an SAF structure.

The directions of easy magnetization of the pinned layers 11A and 11C are perpendicular to the film surface. The magnetization directions of the pinned layers 11A and 11C are antiparallel to each other. The pinned layers 11A and 11C antiferromagnetically couple with each other through the intermediate layer 11B. Use of the SAF structure strengthens the magnetization fixing force of the pinned layer 11 so that the resistance and thermal stability against an external magnetic field improve. In this arrangement, an antiferromagnetic layer may exist under the pinned layer 11A and contacts the pinned layer 11A so that the pinned layer 11A and the antiferromagnetic layer can exchange-couple with each other.

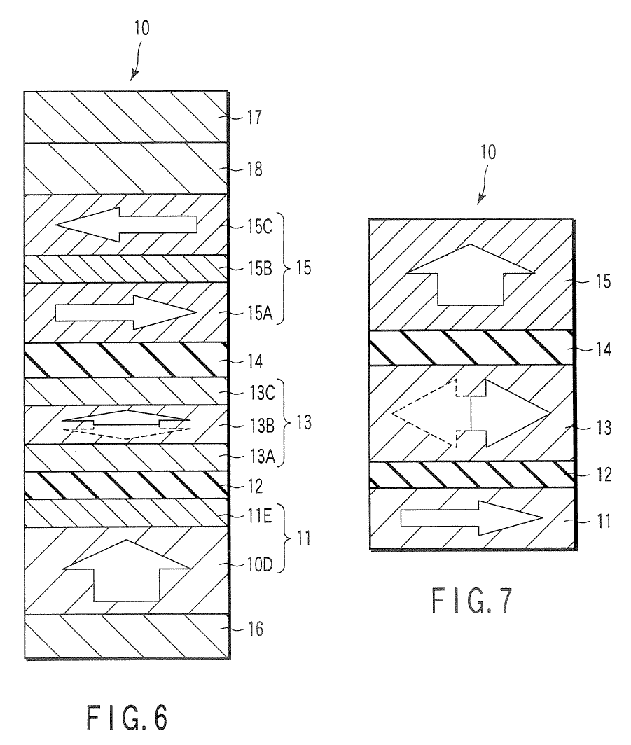

FIG. 6 is a sectional view illustrating another structure of the free layer 13 and pinned layer 11. The free layer 13 has a layered structure of an interface free layer 13C, free layer 13B, and interface free layer 13A. That is, an interface free layer made of a ferromagnetic material preferably exists between the free layer 13B and the intermediate layer 12 or between the free layer 13B and the intermediate layer 14.

As shown in FIG. 6, the pinned layer 11 has a layered structure of an interface pinned layer 11E and a pinned layer 11D. That is, the interface pinned layer 11E made of a ferromagnetic material preferably exists between the pinned layer 11D and the intermediate layer 12.

The interface pinned layer and interface free layer have an effect of enhancing the magnetoresistive effect and an effect of reducing the write current in spin injection write. The interface layer to enhance the magnetoresistive effect is preferably made of a material with a high bulk polarizability and high surface polarizability with respect to the intermediate layer.

The materials of the layers included in the MTJ element 10 will be described next.

### [1] Materials Used for Intermediate Layers 12 and 14

The intermediate layer 12 in the MTJ element 10 of this embodiment uses an insulating material or a semiconductor. In this case, the structure of free layer 13/intermediate layer 12/pinned layer 11 has a tunneling magnetoresistive effect. In read, the magnetization directions of the pinned layer 11 and free layer 13 are parallel or antiparallel. The resistance of the MTJ element 10 becomes high or low. This state is determined as binary 0 or binary 1.

On the other hand, the structure of pinned layer 15/intermediate layer 14/free layer 13 has no tunneling magnetoresistive effect because the magnetization directions of the free layer 13 and pinned layer 15 are perpendicular to each other. Hence, the intermediate layer 14 can use any one of a metal conductor, insulating material, and semiconductor. When an insulating material or semiconductor is used, the resistance of the MTJ element 10 rises. Hence, a metal conductor is preferably used.

The metal conductor used for the intermediate layer 14 is preferably copper (Cu), aluminum (Al), silver (Ag), or gold (Au). When a mixed crystal structure including a conductive metal phase and an insulating phase such as MgO—Cu or AlOₓ—Cu is used to increase the spin injection efficiency by using a current concentration effect of locally increasing the current density, the switching current of the free layer can decrease.

To use the tunneling magnetoresistive effect, the thickness of each of the intermediate layers 12 and 14 is set to 3 nm or less. This is because the resistance and area product (RA) of the MTJ element must be about 100 Ωμm² or less to flow a tunneling current of about 1×10⁵ to 1×10⁷ A/cm² to write data.

Examples of the insulating material used for the intermediate layers 12 and 14 are oxides such as aluminum oxide (Al₂O₃), magnesium oxide (MgO), calcium oxide (CaO), strontium oxide (SrO), titanium oxide (TiO), europium oxide (EuO), zirconium oxide (ZrO), and hafnium oxide (HfO). Examples of the semiconductor are germanium (Ge), silicon (Si), compound semiconductors such as gallium arsenide (GaAs) and indium arsenide (InAs), and oxide semiconductors such as titanium oxide (TiO₂), MgO, CaO, SrO, TiO, and EuO have an NaCl structure.

MgO having an NaCl structure is especially suitable for the intermediate layer 12. This is because the TMR ratio is maximum in use of MgO. Use of MgO enables to obtain a TMR ratio of 100% or more if the RA of the MTJ element falls within the range of 5 to 1,000 (inclusive) Ωμm². MgO having an NaCl structure preferably has a (100) plane orientation as the crystal orientation from the viewpoint of TMR ratio. When an Mg layer of 1 nm or less is inserted on or under the MgO layer in film formation, the TMR ratio can further improve.

The MgO layer is formed by sputtering in a rare gas (argon [Ar], neon [Ne], krypton [Kr], or xenon [Xe]) using an MgO target or oxidation reactive sputtering in an O₂ atmosphere using an Mg target. The MgO layer may be formed by forming an Mg layer and oxidizing it by oxygen radicals, oxygen ions, or ozone. Molecular beam epitaxy (MBE) or electron beam evaporation using MgO is also usable to epitaxially grow the MgO layer.

To obtain a high TMR ratio, the degree of orientation of MgO must be high. The plane orientation of MgO decides the orientation of the magnetic layer serving as the underlying layer to be selected. MgO preferably has a (100) plane orientation. To make MgO have a (100) preferred plane orientation, its underlying layer (free layer, pinned layer, interface free layer, or interface pinned layer) preferably has a body-centered cubic (BCC) structure (100) orientation plane, face-centered cubic (FCC) structure (100) orientation plane, or amorphous structure.

Examples of the material of the BCC structure are BCC—Fe₁₀₀₋ₓCoₓ (0≦x≦70 at (atom) %) and BCC—Co epitaxially grown to 1 nm or less on a BCC structure. BCC—Fe₁₀₀₋ₓ(CoNi)ₓ (0≦x≦70 at %) is also usable. In this case, adding diluted Ni at 10 at % or less increases the TMR ratio by 10% to 20%. Examples of the amorphous material are a cobalt (Co)—iron (Fe)—boron (B) alloy and an Fe—Co—Zr alloy.

### [2] Magnetic Materials Used for Perpendicular Magnetization Free Layer and Perpendicular Magnetization Pinned Layer

In this embodiment, a perpendicular magnetization film is used for the free layer 13 and pinned layer 11. If an in-plane magnetization free layer is used, the switching magnetic field strongly depends on the MTJ element size. However, use of a perpendicular magnetization free layer reduces the dependence on the MTJ element size.

In in-plane magnetization, the shape magnetic anisotropy energy using saturation magnetization maintains the stability of magnetization. For this reason, the switching magnetic field changes depending on the element shape and size. In perpendicular magnetization, saturation magnetization is small, and the magnetocrystalline anisotropy energy independent of the element shape and size maintains the stability of magnetization. For this reason, the switching magnetic field rarely changes depending on the element shape and size. Hence, use of a perpendicular magnetization free layer is preferable for size reduction of the MTJ element because it solves the problem of the MTJ element using an in-plane magnetization film, i.e., prevents the switching magnetic field of the MTJ element from increasing upon reducing the MTJ element size.

The perpendicular magnetization film used in the MTJ element 10 of this embodiment basically contains at least one of iron (Fe), cobalt (Co), nickel (Ni), and manganese (Mn), and at least one of platinum (Pt), palladium (Pd), iridium (Ir), rhodium (Rh), osmium (Os), gold (Au), silver (Ag), copper (Cu), and chromium (Cr). To adjust saturation magnetization, control the magnetocrystalline anisotropy energy, and adjust the crystal grain size and crystal grain bond, at least one element selected from boron (B), carbon (C), silicon (Si), aluminum (Al), magnesium (Mg), tantalum (Ta), zirconium (Zr), titanium (Ti), hafnium (Hf), yttrium (Y), and rare-earth elements may be added. Adding elements enables saturation magnetization Ms and magnetocrystalline anisotropy energy Ku to be reduced without degrading perpendicular magnetization so that the crystal grains can be fragmented and made smaller.

Detailed examples of a material mainly containing Co are a Co—Cr—Pt alloy, Co—Cr—Ta alloy, and Co—Cr—Pt—Ta alloy having a hexagonal closest packing (HCP) structure. These materials can adjust the magnetocrystalline anisotropy energy within the range of 1×10⁵ (inclusive) to 1×10⁷ (exclusive) erg/cc by adjusting the composition of the elements. When these materials are used for the pinned layer close to the substrate, the underlying layer preferably uses Ru having an HCP structure.

A Co—Pt alloy forms an L1₀CoPt ordered alloy in a composition range near Co₅₀Pt₅₀ (at %). This ordered alloy has a face-centered tetragonal (FCT) structure. If the intermediate layer 12 uses MgO (100), an FCT-CoPt ordered alloy having a (001) plane orientation is preferable because it can reduce the interface misfit with respect to the intermediate layer 12. Even an interface layer inserted between the intermediate layer and the free layer (or pinned layer) can readily have a (100) plane orientation.

Detailed examples of a material mainly containing Fe are an Fe—Pt alloy and an Fe—Pd alloy. An Fe—Pt alloy is ordered at a composition of Fe₅₀Pt₅₀ (at %) and has an L1₀ structure based on an FCT structure. The Fe—Pt alloy is also ordered at a composition of Fe₇₅Pt₂₅ (at %) and has an L1₂ structure (Fe₃Pt structure) based on an FCT structure. This produces a high magnetocrystalline anisotropy energy of 1×10⁷ erg/cc or more.

The Fe₅₀Pt₅₀ alloy has an FCC structure before ordering to the L1₀ structure. In this case, the magnetocrystalline anisotropy energy is about 1×10⁶ erg/cc. It is therefore possible to adjust the magnetocrystalline anisotropy energy within the range of 5×10⁵ to 5×10⁸ (both inclusive) erg/cc by adjusting the annealing temperature and composition, controlling the ordering degree based on the layered structure, and addition of an additive. Saturation magnetization before addition is about 800 to 1,100 emu/cc. The saturation magnetization can reduce to 800 emu/cc or less. Using this material for the free layer is preferable from the viewpoint of reduction of the current density Jc.

More specifically, it is possible to control the saturation magnetization (Ms) and magnetocrystalline anisotropy energy (Ku) of an Fe—Pt alloy having an L1₀ ordered structure by adding copper (Cu), titanium (Ti), vanadium (V), manganese (Mn), or chromium (Cr) to the Fe—Pt alloy at 30 at % or less. In addition, V can decrease the damping constant (magnetization damping constant) that is important in spin injection switching and therefore reduce the switching current.

The Fe—Pt alloy ordered to the L1₀ structure or L1₂ structure has an FCT structure. This alloy has an FCC structure before ordering. Hence, the Fe—Pt alloy highly matches to MgO (100). More specifically, BCC-Fe with a (100) plane orientation is grown on an MgO (100) plane, and Pt (100) is stacked on it. An Fe—Pt ordered alloy having an L1₀ structure or L1₂ structure with a (100) preferred orientation grown on MgO (100) can be formed. Forming BCC-Cr between the Fe—Pt ordered alloy and MgO (100) is more preferable because Fe—Pt ordered alloy can have a more preferred (100) plane orientation.

In forming an Fe—Pt ordered alloy with an L1₀ structure or L1₂ structure, an Fe—Pt ordered alloy having an almost ideal L1₀ structure or L1₂ structure can be formed by forming a multilayered structure of [Fe/Pt]n (n is an integer; n≧1). In this case, it is preferable to set the thicknesses of Fe and Pt to 0.1 to 3 (both inclusive) nm. This is essential to obtain a uniform composition state. This is important because it promotes martensitic transformation from an FCC structure to an FCT structure in ordering the Fe—Pt alloy to the L1₀ structure or L1₂ structure.

The Fe—Pt ordered alloy with the L1₀ structure or L1₂ structure has an excellent thermal resistance because its ordering temperature is as high as 500° C. or more. This is a very preferable feature because it ensures a thermal resistance in annealing of the post-process. The ordering temperature can be reduced by adding an element such as Cu or Pd described above at 30 at % or less.

Another example of the perpendicular magnetization film used in the MTJ element 10 of this embodiment is a ferrimagnetic material containing at least one of Fe, Co, Ni, Mn, Cr, and rare-earth elements. Examples of the rare-earth elements are lanthanum (La), cerium (Ce), praseodymium (Pr), neodymium (Nd), promethium (Pm), samarium (Sm), Eu, gadolinium (Gd), terbium (Tb), dysprosium (Dy), holmium (Ho), erbium (Er), thulium (Tm), ytterbium (Yb), and lutetium (Lu).

A ferrimagnetic material containing a rare-earth element has an amorphous structure. This ferrimagnetic material can reduce saturation magnetization to 400 emu/cc or less and increase the magnetocrystalline anisotropy energy to 1×10⁶ erg/cc or more by adjusting the composition.

The perpendicular magnetization film used in the MTJ element 10 of this embodiment may use a ferromagnetic material made of a mixed crystal containing a metal magnetic phase and an insulating phase. The metal magnetic phase is made of a ferromagnetic material containing at least one of Fe, Co, Ni, and Mn and at least one of Pt, Pd, Ir, Rh, Os, Au, Ag, Cu, Cr, Ta, and rare-earth elements. The insulating phase is made of an oxide, nitride, or oxynitride containing at least one element selected from B, C, Si, Al, Mg, Ta, Cr, Zr, Ti, Hf, Y, and rare-earth elements.

A ferromagnetic material made of a mixed crystal containing metal magnetic phase and an insulating phase is divided into a conductive metal magnetic portion and a nonconductive insulating portion. Since a current concentrates to the metal magnetic portion, the energization area decreases, and the local current density increases. This reduces the actually required switching current.

To obtain this effect, it is necessary to control the crystallinity. A two-phase separated structure includes a granular (crystal grain dispersion) structure, island (island-shaped) structure, and columnar (column-shaped) structure. In a columnar structure, a metal magnetic portion vertically extends through a magnetic layer. Hence, a current constriction effect is easy to obtain. In a granular or island structure, a current passes through a path with the smallest tunnel barrier. Hence, a current constriction effect is available, as in the columnar structure.

Other examples of the perpendicular magnetization film used in the MTJ element 10 of this embodiment are Mn ferromagnetic alloys and Cr ferromagnetic alloys. Examples of the Mn ferromagnetic alloys are an Mn—Al alloy, Mn—Au alloy, Mn—Zn alloy, Mn—Ga alloy, Mn—Ir alloy, and Mn—Pt₃ alloy which have an ordered lattice. An example of the Cr ferromagnetic alloy is a Cr—Pt₃ alloy. This alloy has an L1₀ ordered lattice and the characteristic of a ferrimagnetic material.

### [3] Magnetic Materials Used for In-Plane Magnetization Pinned Layer

In this embodiment, an in-plane magnetization film is used for the pinned layer 15 having a magnetization direction perpendicular to the pinned layer 11.

The in-plane magnetization film used in the MTJ element 10 of this embodiment uses a ferromagnetic material containing at least one of Fe, Co, Ni, Mn, and Cr. A detailed example of a material mainly containing Fe, Co, and Ni is an FeₓCo_{y}Ni_{z} alloy (x≧0, y≧0, z≧0, x+y+z=1) having an FCC structure or BCC structure.

The pinned layer preferably uses a half metal material having a high polarizability and capable of theoretically realizing a polarizability of 100%.

An example of the half metal material containing Mn is an Mn ferromagnetic Heusler alloy. An Mn ferromagnetic Heusler alloy has a body-centered cubic system with an ordered lattice represented by A₂MnX. The element A is selected from Cu, Au, Pd, Ni, and Co. The element X is selected from aluminum (Al), indium (In), tin (Sn), gallium (Ga), germanium (Ge), antimony (Sb), and silicon (Si). Of Heusler alloys, a Co₂MnAl alloy having a BCC structure ensures high matching to MgO (100) by having a BCC (100) plane orientation.

The thickness of the ferromagnetic layer in the pinned layer must be 1 nm or more. With a smaller thickness, the ferromagnetic layer can have no continuous film. Hence, it can neither exhibit sufficiently the characteristic of a magnetic layer nor obtain a sufficient magnetoresistive ratio (TMR ratio or giant magnetoresistive (GMR) ratio). The maximum thickness is preferably 3 nm or less. A thickness more than 3 nm largely exceeds the precession length of coherent spin. For this reason, the threshold current necessary for spin injection switching greatly increases.

If the above-described in-plane magnetization pinned layer serves as the underlying layer of the MgO barrier layer, an alloy represented by a compositional formula FeₓCo_{y}Ni_{z} (x≧0, y≧0, z≧0, x+y+z=1) preferably has a (100) plane orientation and a BCC structure. The alloy represented by a compositional formula FeₓCo_{y}Ni_{z} (x≧0, y≧0, z≧0, x+y+z=1) also preferably has an amorphous structure by containing B, C, or N added at a concentration of 30 at % or less. This is because the MgO film readily obtains the (100) preferred plane orientation on a film having an amorphous structure.

### [4] Materials Used for Interface Free Layer and Interface Pinned Layer

The interface pinned layer and interface free layer (both will be referred to as an interface layer hereinafter) shown in FIG. 6 enhance the magnetoresistive effect and also reduce the write current in spin injection write. The interface layer to enhance the magnetoresistive effect is preferably made of a material with a high bulk polarizability and high surface polarizability with respect to the intermediate layer.

The interface layer used in the MTJ element 10 of this embodiment uses a ferromagnetic material containing at least one of Fe, Co, Ni, Mn, and Cr. A detailed example of a material mainly containing Fe, Co, and Ni is an FeₓCo_{y}Ni_{z} alloy (x≧0, y≧0, z≧0, x+y+z=1) having an FCC structure or BCC structure. To reduce the saturation magnetization (Ms) of the Fe—Co—Ni alloy, an (FeₓCo_{y}Ni_{z})₁₀₀₋ₐXₐ alloy (x≧0, y≧0, z≧0, x+y+z=1, a (at %)>0, X is an additional element) is also preferably used. Reduction of the saturation magnetization (Ms) allows large reduction of the switching current. A composition of the Fe—Co—Ni alloy is preferably 50 at % (x+y+z≧50 at %) or more because the coverage in an interface to a barrier layer is 50 at % or more. Hence, degradation in the TMR ratio is suppressed.

Examples of an additive capable of being added while keeping the BCC structure and also capable of reducing the saturation magnetization (Ms) (i.e., the examples of a completely soluble solid solution that can be dissolved as a substitutional solid solution or an additive with a certain solid solution source) are vanadium (V), niobium (Nb), tantalum (Ta), tungsten (W), chromium (Cr), molybdenum (Mo), silicon (Si), gallium (Ga), and germanium (Ge). Among them, V is effective because it can also decrease the damping constant.

It is possible to reduce the saturation magnetization (Ms) by changing the crystal structure to an amorphous structure by adding an interstitial element such as B, C, or N or Zr, Ta, Ti, Hf, Y, or a rare-earth element rarely having a solid solution source. An example of this material is an (FeₓCo_{y}Ni_{z})_{100-b}X_{b} alloy (x≧0, y≧0, z≧0, x+y+z=1, b (at %)>0, X is an additional element such as B, C, N, Zr, Ta, Ti, Hf, Y, or a rare-earth element) having an amorphous structure. To obtain a TMR ratio to some extent, it is important to promote recrystallization partially, i.e., on the interface to MgO.

An example of the material containing Mn is an Mn ferromagnetic Heusler alloy. An Mn ferromagnetic Heusler alloy is a body-centered cubic system alloy with an ordered lattice represented by A₂MnX. The element A is selected from Cu, Au, Pd, Ni, and Co. The element X is selected from Al, In, Sn, Ga, Ge, Sb, and Si. Of Heusler alloys, a Co₂MnAl alloy having a BCC structure ensures high matching to MgO (100) by having a BCC (100) plane orientation. An Mn Heusler alloy sometimes exhibits the conductive characteristic of a half metal.

An oxide material is also usable. An oxide material including a half metal such as Fe₂O₃ is applicable as the interface layer.

The minimum thickness of an interface layer formed on a metal layer such as a free layer or pinned layer must be 0.5 nm or more. The minimum thickness of an interface layer formed on an insulating layer or semiconductor layer must also be 0.5 nm or more. With a smaller thickness, the interface layer can have no continuous film. Hence, it can neither exhibit sufficiently the characteristic of an interface free layer or interface pinned layer nor obtain a sufficient magnetoresistive ratio (TMR ratio or GMR ratio). The maximum thickness is preferably 5 nm or less. A thickness more than 5 nm largely exceeds the precession length of coherent spin. For this reason, the threshold current necessary for spin injection switching greatly increases.

As described above in detail, this embodiment can increase the efficiency of spin injection to the free layer 13 by forming a dual-pin layered structure including two pinned layers with magnetization directions perpendicular to each other. This improves the switching speed of the MTJ element 10. The high spin injection efficiency allows the write current necessary for switching to be decreased.

The magnetization directions of the free layer 13 and pinned layer 11 are parallel to each other. The magnetization directions of the free layer 13 and pinned layer 15 are perpendicular to each other. Although the intermediate layer 12 exhibits a magnetoresistive effect, the intermediate layer 14 exhibits no magnetoresistive effect. This increases the TMR ratio of the MTJ element 10 in reading data.

A conductor such as a metal is usable for the intermediate layer 14 having no magnetoresistive effect. This reduces the resistance of the MTJ element 10.

The free layer 13 uses a perpendicular magnetization film. That is, a magnetocrystalline anisotropy energy ensures the anisotropic magnetic field (Hk) necessary for thermal stability of the free layer 13. Since the aspect ratio of the free layer 13 can be low, the MTJ element size can be reduced.

An interface free layer made of a ferromagnetic material is inserted between the free layer 13 and the intermediate layer 12 or between the free layer 13 and the intermediate layer 14. An interface pinned layer made of a ferromagnetic material is inserted between the pinned layer 11 and the intermediate layer 12. The interface free layer and interface pinned layer use a material with a high bulk polarizability so that the magnetoresistive effect can be enhanced. This also decreases the write current.

More detailed examples of the layered structure of the TMR film used in the MTJ element are as follows. In Examples 1 to 3, the numerical value following each layer represents thickness.

### EXAMPLE 1

Ta5/PtMn15/CoFe2.5/Ru0.85/CoFe2.5/Cu3(intermediate layer

14)/CoFeB0.5/FePt(L1₀)2/Fe0.5/MgO0.75(intermediate layer

12)/CoFeB1/FePt(L1₀)10/Pt5/Cr20/MgO2/CoFeB2/Ta5//substrate

### EXAMPLE 2

Ta5/IrMn10/CoFe2.5/Ru0.85/CoFe2.5/Cu3(intermediate layer

14)/CoFeB0.5/CoFeTb3/CoFeB0.75/MgO0.75(intermediate layer 12)/CoFeB2/CoFeTb30/Ru5/Ta5//substrate

### EXAMPLE 3

Ta5/IrMn10/CoFe2.5/Ru0.85/CoFe2.5/Cu3(intermediate layer 14)/CoFeB0.5/CoPt3/CoFeB0.5/MgO0.75(intermediate layer 12)/CoFeB2/CoPt20/Ru10/Ta5//substrate

In Examples 1 and 3, annealing was executed in an in-plane magnetic field in vacuum at 270° C. MTJ elements capable of 4-terminal measurement were formed by using these MTJ films, and the current density Jc necessary for spin injection switching was evaluated. Measurement was done at a pulse width of 1 msec. The MTJ element size was about 100 nm×100 nm, and the aspect ratio was 1. The MgO thickness was adjusted such that the resistance and area product (RA) of each MTJ element became 15 Ωμm².

Each example was compared with a comparative example having no in-plane magnetization pinned layer on the intermediate layer 14. The current density Jc decreased by about 10% to 30%. In each example, the intermediate layer 14 used Cu. Hence, the resistance and area product (RA) rarely increased. No large degradation in TMR ratio was observed.

### Second Embodiment

In the second embodiment, an MTJ element 10 is formed by using an in-plane magnetization film for a free layer 13. FIG. 7 is a sectional view illustrating the MTJ element 10 according to the second embodiment. FIG. 7 shows the basic structure of the MTJ element 10 according to this embodiment.

The MTJ element 10 has a layered structure of a first pinned layer 11, first intermediate layer 12, free layer 13, second intermediate layer 14, and second pinned layer 15 which are stacked in this order. In this basic structure, the order of stacked layers may reverse.

The directions of easy magnetization of the pinned layer 11 and free layer 13 are parallel to the film surface. The direction of easy magnetization of the pinned layer 15 is perpendicular to the film surface. That is, the directions of easy magnetization of the pinned layers 11 and 15 are perpendicular to each other. Hence, a magnetoresistive effect appears, via the intermediate layer 12, between the free layer 13 and the pinned layer 11 with a parallel magnetization arrangement. However, no magnetoresistive effect appears, via the intermediate layer 14, between the free layer 13 and the pinned layer 15 with a perpendicular magnetization arrangement.

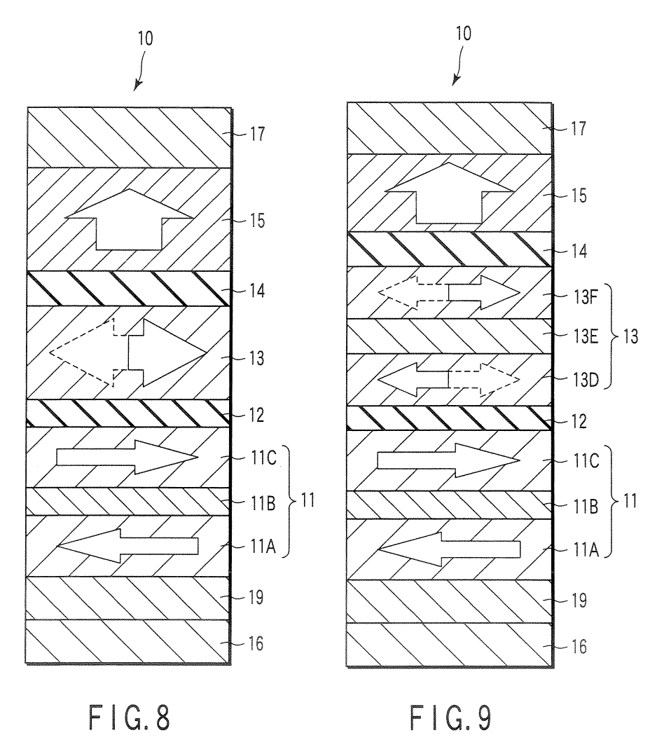

FIG. 8 is a sectional view illustrating a detailed example of the NTJ element 10. A cap layer 17 and an underlying layer 16 exist at the uppermost and lowermost portions of the basic structure shown in FIG. 7, respectively. The pinned layer 11 has a layered structure of a pinned layer 11C, intermediate layer 11B, and pinned layer 11A. That is, the pinned layer 11 has an SAF structure.

The directions of easy magnetization of the pinned layers l1A and 11C are parallel to the film surface. The magnetization directions of the pinned layers 11A and 11C are antiparallel to each other. The pinned layers 11A and 11C antiferromagnetically couple with each other through the intermediate layer 11B. The intermediate layer in the SAF structure uses a metal material such as Ru or Os and has a thickness of 3 nm or less in order to obtain sufficiently strong antiferromagnetic coupling through the intermediate layer.

An antiferromagnetic layer 19 exists under the pinned layer 11A (between the pinned layer 11A and the underlying layer 16) and contacts the pinned layer 1lA. The pinned layer 11A exchange-couples with the antiferromagnetic layer 19 so that the magnetization direction is fixed parallel to the film surface.

Use of this structure strengthens the magnetization fixing force of the pinned layer 11 so that the resistance and thermal stability against an external magnetic field improve. To improve the resistance against an external magnetic field, apparently a product Ms·t of the saturation magnetization and the magnetic layer thickness of the pinned layer 11 is preferably almost zero.

FIG. 9 is a sectional view illustrating another structure of the free layer 13. The free layer 13 has a layered structure of a free layer 13F, intermediate layer 13E, and free layer 13D. That is, the free layer 13 has an SAF structure. The directions of easy magnetization of the free layers 13D and 13F are parallel to the film surface. The magnetization directions of the free layers 13D and 13F are antiparallel to each other. The free layers 13D and 13F antiferromagnetically couple with each other through the intermediate layer 13E.

The MTJ element 10 having the above-described structure can also obtain the same effect as in the first embodiment. An interface layer may be inserted in the free layer 13 and pinned layer 11, as described in the first embodiment.

The free layer 13 of this embodiment mainly uses an Fe—Co—Ni alloy. To reduce saturation magnetization (Ms) of the Fe—Co—Ni alloy, an (FeₓCo_{y}Ni_{z})₁₀₀₋ₐXₐ alloy (x≧0, y≧0, z≧0, x+y+z=1, a (at %)>0, X is an additional element) is also preferably used. Reduction of the saturation magnetization (Ms) allows large reduction of the switching current.

Examples of an additive capable of being added while keeping the BCC structure and also capable of reducing the saturation magnetization (Ms), (i.e., examples of a completely soluble solid solution that can be dissolved as a substitutional solid solution or an additive with a certain solid solution source) are V, Nb, Ta, W. Cr. Mo, Si, Ga, and Ge. Among them, V is effective because it can also decrease the damping constant.

It is possible to reduce the saturation magnetization (Ms) by changing the crystal structure to an amorphous structure by adding an interstitial element such as B. C, or N or Zr, Ta, Ti, Hf. Y, or a rare-earth element rarely having a solid solution source. An example of this material is an (FeₓCo_{y}Ni_{z})_{100-b}X_{b} alloy (x≧0, y≧0, z≧0, x+y+z=1, b (at %)>0, X is an additional element such as B, C, N, Zr, Ta, Ti, Hf, Y, or a rare-earth element) having an amorphous structure.

An example of the material containing Mn is an Mn ferromagnetic Heusler alloy. A Heusler alloy exhibits the conductive characteristic of a half metal. An Mn ferromagnetic Heusler alloy is a body-centered cubic system alloy with an ordered lattice represented by A₂MnX. The element A is selected from Cu, Au, Pd, Ni, and Co. The element X is selected from Al, In, Sn, Ga, Ge, Sb, and Si. Of Heusler alloys, a Co₂MnAl alloy having a BCC structure ensures high matching to MgO (100) by having a BCC (100) plane orientation.

The materials described in the first embodiment are usable even for the remaining layers included in the MTJ element 10.

### Third Embodiment

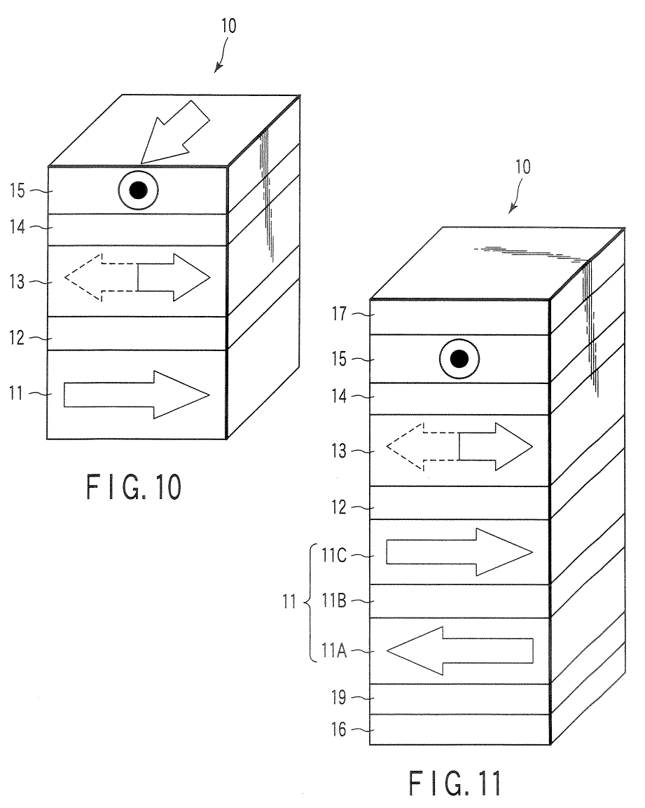

In the third embodiment, an MTJ element 10 is formed by using an in-plane magnetization film for each of a free layer 13 and two pinned layers. FIG. 10 is a perspective view illustrating the MTJ element 10 according to the third embodiment. FIG. 10 shows the basic structure of the MTJ element 10 according to this embodiment.

The MTJ element 10 has a layered structure of a first pinned layer 11, first intermediate layer 12, free layer 13, second intermediate layer 14, and second pinned layer 15 which are stacked in this order. In this basic structure, the order of stacked layers may reverse.

The directions of easy magnetization of the pinned layer 11, free layer 13, and pinned layer 15 are parallel to the film surface. That is, an in-plane magnetization film is usable for all magnetic layers. This facilitates formation of the MTJ element 10.

The directions of easy magnetization of the pinned layer 11 and free layer 13 are parallel. The directions of easy magnetization of the pinned layers 11 and 15 are perpendicular to each other. Hence, a magnetoresistive effect appears, via the intermediate layer 12, between the free layer 13 and the pinned layer 11 with a parallel magnetization arrangement. However, no magnetoresistive effect appears, via the intermediate layer 14, between the free layer 13 and the pinned layer 15 with a perpendicular magnetization arrangement.

FIG. 11 is a perspective view illustrating a detailed example of the MTJ element 10. A cap layer 17 and an underlying layer 16 exist at the uppermost and lowermost portions of the basic structure shown in FIG. 11, respectively. The pinned layer 11 has a layered structure of a pinned layer 11C, intermediate layer 11B, and pinned layer 11A. That is, the pinned layer 11 has an SAF structure. The directions of easy magnetization of the pinned layers 11A and 11C are parallel to the film surface. The magnetization directions of the pinned layers 11A and 11C are antiparallel to each other. The pinned layers 11A and 11C antiferromagnetically couple with each other through the intermediate layer 11B.

An antiferromagnetic layer 19 exists under the pinned layer 11A (between the pinned layer 11A and the underlying layer 16) and contacts the pinned layer 11A. The pinned layer 11A exchange-couples with the antiferromagnetic layer 19 so that the magnetization direction is fixed parallel to the film surface. Use of this structure strengthens the magnetization fixing force of the pinned layer 11 so that the resistance and thermal stability against an external magnetic field improve.

The pinned layer 15 and free layer 13 must have an obvious coercive force difference. Hence, the pinned layer 15 preferably uses an in-plane magnetization type hard magnetic layer.

Examples of the material of the in-plane magnetization type hard magnetic layer are a Co—Pt alloy and Co—Pt—X alloy (X is at least one element selected from Cr, Ta, Pd, B, Si, and Ru). It is also possible to form an SAF structure including a hard magnetic layer, intermediate layer, and hard magnetic layer using an in-plane magnetization type hard magnetic layer. In this case, the intermediate layer uses Ru or Os.

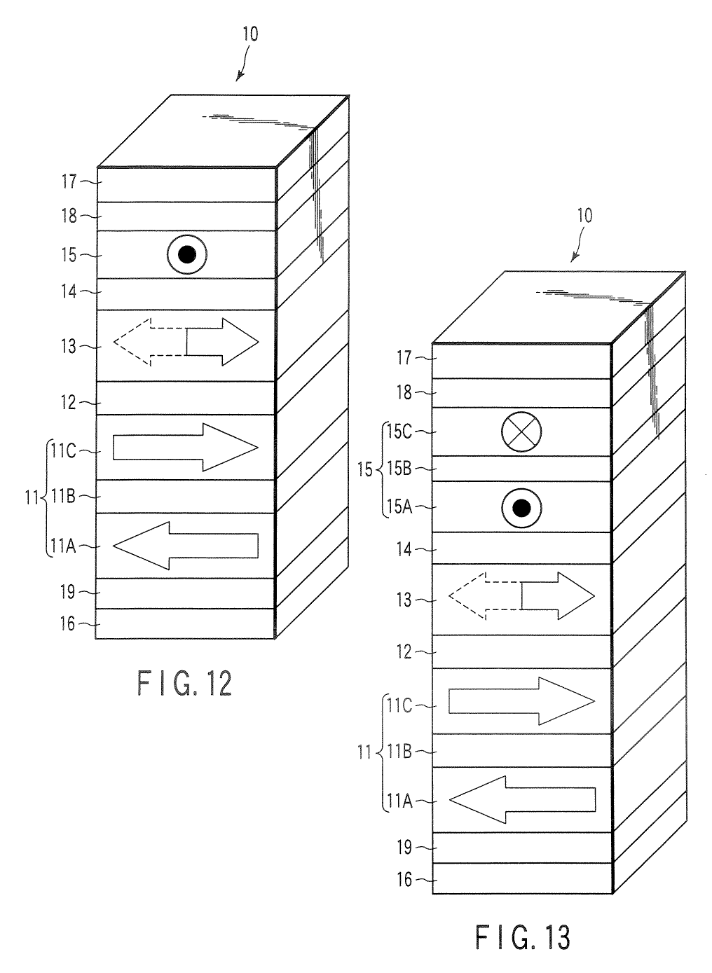

FIG. 12 is a perspective view illustrating another structure of the pinned layer 15. An antiferromagnetic layer 18 exists on the pinned layer 15 (between the pinned layer 15 and the cap layer 17) and contacts the pinned layer 15. The pinned layer 15 exchange-couples with the antiferromagnetic layer 18 so that the magnetization direction is fixed parallel to the film surface.

FIG. 13 is a perspective view illustrating still another structure of the pinned layer 15. The pinned layer 15 has a layered structure of a pinned layer 15C, intermediate layer 15B, and pinned layer 15A. That is, the pinned layer 15 has an SAF structure. The directions of easy magnetization of the pinned layers 15A and 15C are parallel to the film surface. The magnetization directions of the pinned layers 15A and 15C are antiparallel to each other. The pinned layers 15A and 15C antiferromagnetically couple with each other through the intermediate layer 15B.

The antiferromagnetic layers 19 and 18 shown in FIGS. 12 and 13 can make the directions of easy magnetization of the pinned layers 11 and 15 perpendicular to each other by executing an annealing sequence at different critical temperatures, i.e., blocking temperatures for coupling with a ferromagnetic layer. More specifically, it is preferable to use a material such as PtMn or NiMn with a high blocking temperature for the antiferromagnetic layer 19 and a material such as FeMn or IrMn with a relatively low blocking temperature for the antiferromagnetic layer 18.

The free layer 13 may have a layered structure of a ferromagnetic layer, intermediate layer, and ferromagnetic layer, i.e., an SAF structure. In the SAF structure, the magnetization directions of the ferromagnetic layers are antiparallel to each other. The ferromagnetic layers antiferromagnetically couple with each other through the intermediate layer.

The MTJ element 10 having the above-described structure can also obtain the same effect as in the first embodiment. An interface layer may be inserted in the free layer 13 and pinned layer 11, as described in the first embodiment. The materials described in the first and second embodiments are usable even for the remaining layers included in the MTJ element 10.

### Fourth Embodiment

In the fourth embodiment, an MRAM is formed by using the above-described MTJ element 10.

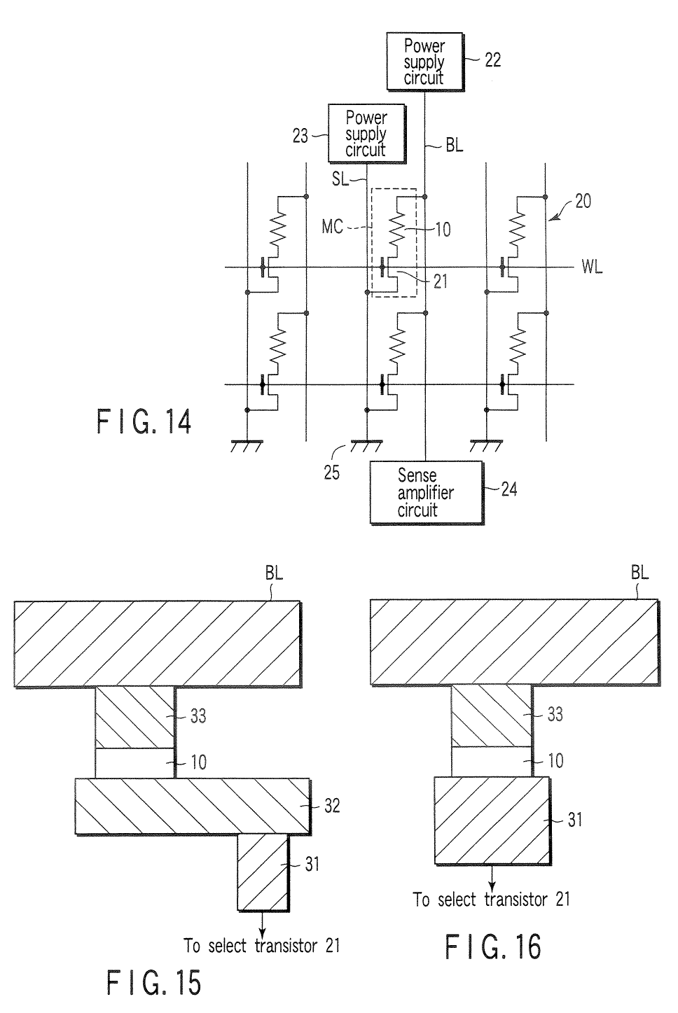

FIG. 14 is a circuit diagram illustrating an MRAM according to the fourth embodiment. The MRAM comprises a memory cell array 20 having a plurality of memory cells MC arrayed in a matrix. The memory cell array 20 has a plurality of bit lines BL running in the column direction. The memory cell array 20 has a plurality of word lines WL running in the row direction.

The above-described memory cell MC is arranged at the intersection between the bit line BL and the word line WL. Each memory cell MC includes the MTJ element 10 and a select transistor 21. One terminal of the MTJ element 10 connects to the bit line BL. The other terminal of the MTJ element 10 connects to the drain of the select transistor 21. The word line WL connects to the gate of the select transistor 21. The source of the select transistor 21 connects to a source line SL.

A power supply circuit 22 connects to one end of the bit line BL. A sense amplifier circuit 24 connects to the other end of the bit line BL. A power supply circuit 23 connects to one end of the source line SL. The other end of the source line SL connects to a power supply 25 through a switching element (not shown).

The power supply circuit 22 applies a positive potential to one end of the bit line BL. The sense amplifier circuit 24 detects the resistance of the MTJ element 10 and applies, e.g., ground potential to the other end of the bit line BL. The power supply circuit 23 applies a positive potential to one end of the source line SL. The power supply 25 turns on the switching element connected to it to apply, e.g., the ground potential to the other end of the source line SL. Each power supply circuit includes a switching element to control electrical connection to a corresponding interconnection.

Data is written in the memory cell MC in the following way. First, to select the memory cell MC to be accessed to write data, the word line WL connected to the memory cell MC is activated so that the select transistor 21 is turned on.

A bidirectional write current Iw is supplied to the MTJ element 10. More specifically, when the write current Iw is supplied to the MTJ element 10 from the upper side to the lower side, the power supply circuit 22 applies a positive potential to one end of the bit line BL. The power supply 25 turns on a switching element corresponding to the power supply 25 to apply the ground potential to the other end of the source line SL.

When the write current Iw is supplied to the MTJ element 10 from the lower side to the upper side, the power supply circuit 23 applies a positive potential to one end of the source line SL. The sense amplifier circuit 24 applies the ground potential to the other end of the bit line BL. The switching element corresponding to the power supply 25 is off. This enables binary 0 or binary 1 to be written to the memory cell MC.

Data is read from the memory cell MC in the following way. First, the memory cell MC is selected. The power supply circuit 23 and sense amplifier circuit 24 supply, to the MTJ element 10, a read current Ir flowing from the power supply circuit 23 to the sense amplifier circuit 24. On the basis of the read current Ir, the sense amplifier circuit 24 detects the resistance of the MTJ element 10. This enables data to be read from the MTJ element 10.

The structure of the MRAM will be described next. FIG. 15 is a sectional view illustrating an MRAM so as to mainly show the MTJ element 10. The MTJ element 10 is formed, through an interlayer dielectric film, above the select transistor 21 formed in a semiconductor substrate (not shown) made of, e.g., silicon.

The MTJ element 10 is provided on an extraction electrode 32. The extraction electrode 32 electrically connects to the drain region of the select transistor 21 through a via plug 31. A hard mask 33 is provided on the MTJ element 10. The bit line BL is provided on the hard mask 33.

The bit line BL, hard mask 33, and via plug 31 use, e.g., W, Al, Cu, or AlCu. A metal interconnection layer or via plug using Cu is formed by a Cu damascene or Cu dual damascene process.

FIG. 16 is a sectional view illustrating another structure of the MRAM so as to mainly show the MTJ element 10. The MTJ element 10 is provided directly on the via plug 31. That is, the MRAM shown in FIG. 16 has no extraction electrode 32, unlike the MRAM shown in FIG. 15. The hard mask 33 is provided on the MTJ element 10. The bit line BL is provided on the hard mask 33.

The MTJ element 10 electrically connects to the via plug 31 through the extraction electrode 32, as shown in FIG. 15, or is directly formed on the via plug 31, as shown in FIG. 16. In the structure shown in FIG. 16, the MTJ element is preferably smaller than the via plug.

Let F be the minimum feature size decided by lithography or etching. In the layout shown in FIG. 15, the minimum cell size is 8F². In the layout shown in FIG. 16, the minimum cell size can decrease to 4F².

In the MRAM with the above-described structure, the speed of writing to the MTJ element 10 can increase. More specifically, it is possible to execute spin injection write by a current having a pulse width of several nsec to several msec.

The pulse width of the read current Ir supplied to the MTJ element 10 is preferably shorter than that of the write current Iw supplied to the MTJ element 10. This reduces write errors by the read current Ir. This is because the shorter the pulse width of the write current Iw becomes, the larger the absolute value of the write current becomes.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A magnetoresistive element comprising:
a first magnetic reference layer having a fixed magnetization direction;
a magnetic free layer having a magnetization direction which is changeable by being supplied with spin polarized electrons;
a second magnetic reference layer having a fixed magnetization direction;
a first intermediate layer provided between the first magnetic reference layer and the magnetic free layer; and
a second intermediate layer provided between the magnetic free layer and the second magnetic reference layer,
wherein the magnetic free layer and the first magnetic reference layer have directions of easy magnetization perpendicular or parallel to an in-plane direction, and
the first magnetic reference layer and the second magnetic reference layer have directions of easy magnetization perpendicular to each other.

2. The element according to claim 1, wherein:
the magnetic free layer and the first magnetic reference layer have directions of easy magnetization perpendicular to the in-plane direction; and
the second magnetic reference layer has a direction of easy magnetization parallel to the in-plane direction.

3. The element according to claim 1, wherein the first magnetic reference layer, the magnetic free layer, and the second magnetic reference layer have directions of easy magnetization parallel to the in-plane direction.

4. The element according to claim 1, wherein the first intermediate layer is made of one of an insulating material and a semiconductor.

5. The element according to claim 1, wherein the second intermediate layer is made of a conductor.

6. The element according to claim 1, wherein:
the magnetic free layer includes a first magnetic layer, a second magnetic layer, and a third magnetic layer which are stacked in order;
the first magnetic layer is arranged in contact with the first intermediate layer; and
the third magnetic layer is arranged in contact with the second intermediate layer.

7. The element according to claim 6, wherein the first magnetic layer and the third magnetic layer are made of a ferromagnetic material.

8. The element according to claim 1, wherein:
the first magnetic reference layer includes a first magnetic layer and a second magnetic layer which are stacked;
the first magnetic layer is arranged in contact with the first intermediate layer.

9. The element according to claim 8, wherein the first magnetic layer is made of a ferromagnetic material.

10. The element according to claim 1, wherein the first magnetic reference layer includes a first magnetic layer, a nonmagnetic layer, and a second magnetic layer which are stacked in order.

11. The element according to claim 10, wherein magnetization directions of the first magnetic layer and the second magnetic layer are set to opposite directions.

12. The element according to claim 1, wherein the second magnetic reference layer includes a first magnetic layer, a nonmagnetic layer, and a second magnetic layer which are stacked in order.

13. The element according to claim 12, wherein magnetization directions of the first magnetic layer and the second magnetic layer are set to opposite directions.

14. The element according to claim 1, wherein the magnetic free layer includes a first magnetic layer, a nonmagnetic layer, and a second magnetic layer which are stacked in order.

15. The element according to claim 14, wherein magnetization directions of the first magnetic layer and the second magnetic layer are set to opposite directions.

16. The element according to claim 1, further comprising an antiferromagnetic layer which fixes the magnetization direction of the first magnetic reference layer by an exchange coupling force.

17. The element according to claim 1, further comprising an antiferromagnetic layer which fixes the magnetization direction of the second magnetic reference layer by an exchange coupling force.

18. A magnetic memory comprising a memory cell including:
a magnetoresistive element; and
a first electrode and a second electrode which supply the current to the magnetoresistive element, the magnetoresistive element comprising:
a first magnetic reference layer having a fixed magnetization direction;
a magnetic free layer having a magnetization direction which is changeable by being supplied with spin polarized electrons;
a second magnetic reference layer having a fixed magnetization direction;
a first intermediate layer provided between the first magnetic reference layer and the magnetic free layer; and
a second intermediate layer provided between the magnetic free layer and the second magnetic reference layer,
the magnetic free layer and the first magnetic reference layer having directions of easy magnetization perpendicular or parallel to an in-plane direction, and
the first magnetic reference layer and the second magnetic reference layer having directions of easy magnetization perpendicular to each other.

19. The memory according to claim 18, further comprising a power supply circuit which electrically connects to the first electrode and the second electrode, and bidirectionally supplies the current to the magnetoresistive element.

20. The memory according to claim 19, wherein the memory cell includes a select transistor which electrically connects to the second electrode and the power supply circuit.
